(19) United States
(12) Patent Application Publication
(10) Pub. No.: US 2012/0194206 A1
(43) Pub. Date: Aug. 2, 2012

(54) Measuring Apparatus

(75) Inventors: Takeshi NAGASAKA, Gunma (JP); Keith SCHAUB, Austin, TX (US); Anthony Lum, Chandler, AZ (US)

(73) Assignee: ADVANTEST CORPORATION, Tokyo (JP)

(21) Appl. No.: 13/016,048

(22) Filed: Jan. 28, 2011

(51) Int. Cl. G01R 31/00

(52) U.S. Cl. 324/750.01

(57) ABSTRACT

A test for connecting a transmitter and a receiver of a device under test with each other is carried out by a measurement device. The measurement device 100 connected to a device under test 200 including a transmission unit 202 and a reception unit 204 includes an input port 102 connected to the transmission unit 202, an output port 104 connected to the reception unit 204, signal output units 132, 134 that output an output signal, electric power measurement units 145, 155 that measure the electric power of an input signal, a connection unit (coupler 110, switches 120-128) that can connect the input port to the output port 104 and/or the electric power measurement units 145, 155, and can connect the output port 104 to the input port 102 and/or the signal output units 132, 134, and electric power adjustment units 183, 185 that adjust the electric power of an output port signal output from the output port 104 if the input port 102 and the output port 104 are connected with each other.

### BACKGROUND ART

1. Technical Field of the Invention

The present invention relates to a measurement device which includes a signal output unit and an electric power measurement unit.

2. Related Art

A transmitter/receiver which includes a noise source and a receiver has conventionally known (refer to FIG. 2 of a patent document 1 (Japanese Patent Application Laid-Open No. 2009-288019), for example), and it is conceived that a wireless communication function unit (RF unit), which is a semiconductor device, is tested by using the transmitter/receiver. However, the number of RF pins of the RF unit is increasing in order to comply with multiple communication standards, and the cost for the test of the RF unit increases accordingly.

To address this problem, a built in system test (BIST) may be installed in the RF unit. The built in system test can permit a test by connecting the transmitter and the receiver of the RF unit inside the semiconductor device.

### SUMMARY OF THE INVENTION

An object of the present invention is to carry out a test of connecting a transmitter and a receiver of a device under test by a measurement device.

According to the present invention, a measurement device connected to a device under test including a transmission unit and a reception unit, includes: an input port connected to the transmission unit; an output port connected to the reception unit; a signal output unit that outputs an output signal; an electric power measurement unit that measures the electric power of an input signal; a connection unit that can connect the input port to the output port and/or the electric power measurement unit, and can connect the output port to the input port and/or the signal output unit; and an electric power adjustment unit that adjusts the electric power of an output port signal output from the output port if the input port and the output port are connected with each other.

The thus constructed measurement device is connected to a device under test including a transmission unit and a reception unit. According to the measurement device, an input port is connected to the transmission unit. An output port is connected to the reception unit. A signal output unit outputs an output signal. An electric power measurement unit measures the electric power of an input signal. A connection unit can connect the input port to the output port and/or the electric power measurement unit, and can connect the output port to the input port and/or the signal output unit. An electric power adjustment unit adjusts the electric power of an output port signal output from the output port if the input port and the output port are connected with each other.

According to the measurement device of the present invention, the connection unit may connect the input port and the electric power measurement unit, then connect the input port and the output port with each other; and the electric power adjustment unit may adjust the electric power of the output port signal according to a measurement result by the electric power measurement unit if the input port and the output port are connected with each other.

According to the measurement device of the present invention, the connection unit may connect the input port and the output port, and simultaneously connect the output port and the signal output unit.

According to the measurement device of the present invention, the output port signal may include an output signal component which is the output signal, and has reached the output port, and an input port signal component which is an input port signal, is input from the input port, and has reached the output port if the input port and the output port are connected with each other; and the electric power adjustment unit may adjust a ratio between the electric power of the output signal component and the electric power of the input port signal component contained in the output port signal if the input port and the output port are connected with each other.

According to the measurement device of the present invention, the connection unit may connect the input port and the output port, and simultaneously connect the output port and the signal output unit; the output port signal may include an output signal component which is the output signal and has reached the output port; and the electric power adjustment unit may adjust the electric power of the output signal component.

According to the measurement device of the present invention, the output signal may be a continuous wave signal or a noise.

According to the measurement device of the present invention, the input port and the output port may be mutually replaceable.

### BRIEF DESCRIPTION OF THE DRAWINGS

FIG. 1 is a functional block diagram showing a configuration of a measurement device 100 according to a first embodiment of the present invention (an input port 102 and a measurement unit 145 are connected with each other);

FIG. 2 is a functional block diagram showing a configuration of the measurement device 100 according to the first embodiment of the present invention (the input port 102 and an output port 104 are connected with each other);

FIG. 3 is a functional block diagram showing a configuration of the measurement device 100 according to a variation of the first embodiment of the present invention (the input port 102 and the measurement unit 155 are connected with each other);

FIG. 4 is a functional block diagram showing a configuration of the measurement device 100 according to the variation of the first embodiment of the present invention (the input port 102 and the output port 104 are connected with each other);

FIG. 5 is a functional block diagram showing a configuration of the measurement device 100 according to the second embodiment of the present invention (the continuous wave signal source 132 and the output port 104 are connected with each other);

FIG. 6 is a functional block diagram showing a configuration of the measurement device 100 according to the second embodiment of the present invention (the noise source 134 and the output port 104 are connected with each other);

FIG. 7 is a functional block diagram showing a configuration of the measurement device 100 according to a variation of the second embodiment of the present invention (the continuous wave signal source 132 and the output port 104 are connected with each other);

FIG. 8 is a functional block diagram showing a configuration of the measurement device 100 according to the variation of the second embodiment of the present invention (the noise source 134 and the output port 104 are connected with each other);

FIG. 9 is a functional block diagram showing a configuration of the measurement device 100 according to the third embodiment of the present invention (the input port 102 and the measurement unit 145 are connected with each other);

FIG. 10 is a functional block diagram showing a configuration of the measurement device 100 according to the third embodiment of the present invention (the continuous wave signal source 132 and the output port 104 are connected with each other);

FIG. 11 is a functional block diagram showing a configuration of the measurement device 100 according to the third embodiment of the present invention (the noise source 134 and the output port 104 are connected with each other);

FIG. 12 is a functional block diagram showing a configuration of the measurement device 100 according to a variation of the third embodiment of the present invention (the input port 102 and the measurement unit 155 are connected with each other);

FIG. 13 is a functional block diagram showing a configuration of the measurement device 100 according to the variation of the third embodiment of the present invention (the continuous wave signal source 132 and the output port 104 are connected with each other);

FIG. 14 is a functional block diagram showing a configuration of the measurement device 100 according to the variation of the third embodiment of the present invention (the noise source 134 and the output port 104 are connected with each other);

FIG. 15 is a functional block diagram showing a connection example in which the output port 104 is connected to the noise source 134 in the measurement device 100;

FIG. 16 is a functional block diagram showing a connection example in which the input port 102 is connected to the measurement unit 145 and the output port 104 in the measurement device 100;

FIG. 17 is a functional block diagram showing a configuration of the measurement device 100 according to the fourth embodiment of the present invention (the noise source 134 and the input port 102, and the output port 104 are connected with each other);

FIG. 18 is a functional block diagram showing a configuration in which the measurement device 100 according to the fourth embodiment of the present invention is used as an ordinary measurement device (the noise source 134 and the output port 104 are connected with each other);

FIG. 19 is a functional block diagram showing a configuration of the measurement device 100 according to a variation of the fourth embodiment of the present invention (the noise source 134 and the input port 102, and the output port 104 are connected with each other); and

FIG. 20 is a functional block diagram showing a configuration in which the measurement device 100 according to the variation of the fourth embodiment of the present invention is used as an ordinary measurement device (the noise source 134 and the output port 104 are connected with each other).

### PREFERRED EMBODIMENTS

A description will now be given of embodiments of the present invention referring to drawings.

### First Embodiment

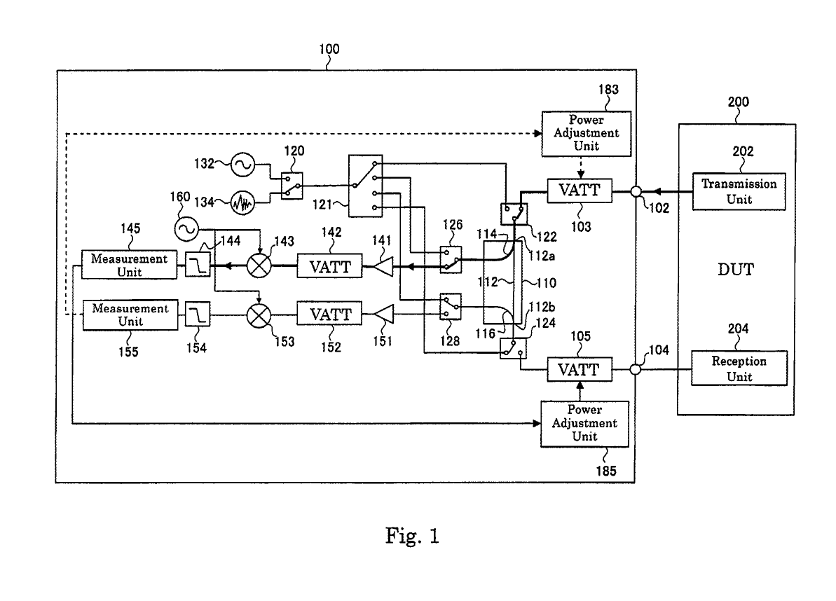

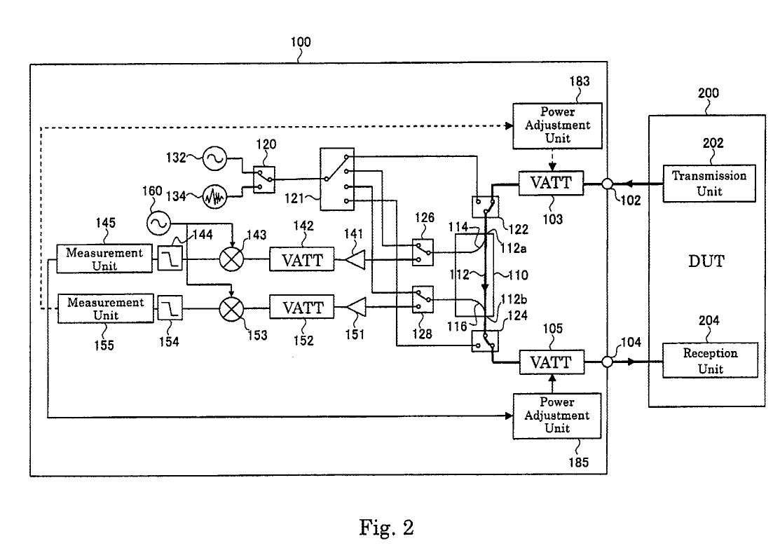

FIG. 1 is a functional block diagram showing a configuration of a measurement device 100 according to a first embodiment of the present invention (an input port 102 and a measurement unit 145 are connected with each other). FIG. 2 is a functional block diagram showing a configuration of the measurement device 100 according to the first embodiment of the present invention (the input port 102 and an output port 104 are connected with each other).

The measurement device 100 according to the first embodiment of the present invention is connected to a device under test (DUT) 200. The DUT 200 includes a transmission unit 202 and a reception unit 204. The transmission unit 202 and the reception unit 204 are wireless communication function units (RF units), for example.

The measurement device 100 according to the first embodiment includes the input port 102, the output port 104, variable attenuators (VATTs) 103, 105, the coupler 110, switches 120, 121, 122, 124, 126, 128, a continuous wave signal source (signal output unit) 132, a noise source (signal output unit) 134, amplifiers 141, 151, variable attenuators (VATTs) 142, 152, mixers 143, 153, low-pass filters 144, 154, measurement units (electric power measurement units) 145, 155, a local signal source 160, and power adjustment units (electric power adjustment units) 183, 185.

The input port 102 is connected to the transmission unit 202. The output port 104 is connected to the reception unit 204.

The variable attenuator (VATT) 103 is connected to the input port 102, attenuates an input, and outputs the attenuated input. It should be noted that the ratio between the input and the output is variable. The variable attenuator (VATT) 105 is connected to the output port 104, attenuates an input, and outputs the attenuated input. It should be noted that the ratio between the input and the output is variable.

The continuous wave signal source (signal output unit) 132 outputs a continuous wave signal. This continuous wave signal is a non-modulated sinusoidal wave, for example. The noise source (signal output unit) 134 outputs noise. The continuous wave signal source 132 and the noise source 134 are the signal output units which output an output signal. In other words, the output signal is the continuous wave signal or the noise.

The local signal source 160 outputs a local signal at a predetermined frequency, and feeds the local signal to the mixers 143, 153.

The amplifiers 141, 151 receive an input, amplify the input, and output the amplified input. The variable attenuators (VATTs) 142, 152 receive respectively the outputs from the amplifiers 141, 151, attenuate the outputs, and output the attenuated outputs. It should be noted that the degree of the attenuation is variable. The mixers 143, 153 respectively receive the outputs from the VATTs 142, 152, mix the outputs with the local signals, and output the mixed signals. The low-pass filters 144, 154 receive the outputs from the mixers 143, 153, remove (or suppress) a high-frequency component, and output the filtered outputs. The outputs from the low-pass filters 144, 154 are respectively input to the measurement units 145, 155, and are referred to as input signals.

The measurement units 145, 155 respectively measure the electric powers of the input signals (outputs from the low pass filters 144, 154). The measurement units 145, 155 convert the input signals (which are analog) into digital signals, and measure the electric powers of the input signals based on the digital signals.

The power adjustment unit (electric power adjustment unit) 185 adjusts the electric power of an output port signal output from the output port 104 if the input port 102 and the output port 104 are connected with each other. Specifically, the power adjustment unit (electric power adjustment unit) 185 adjusts the electric power of the output port signal by adjusting the ratio between the input and the output of the VATT 105.

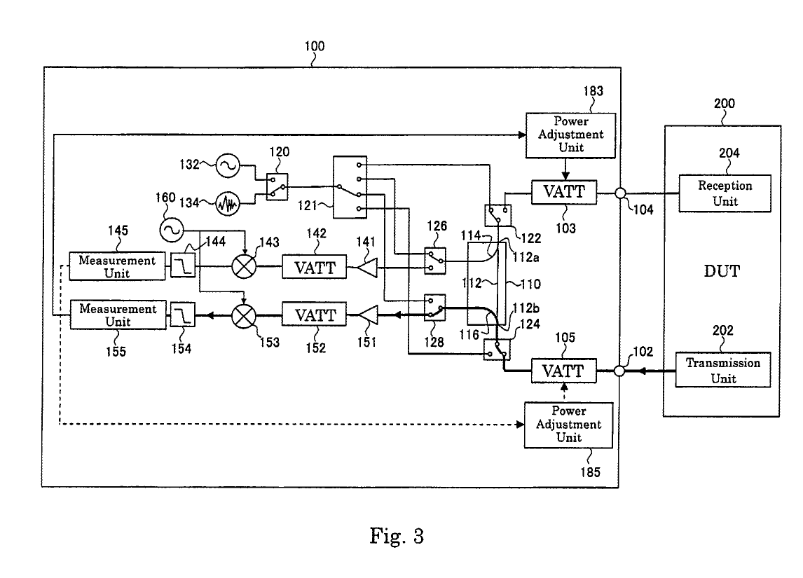

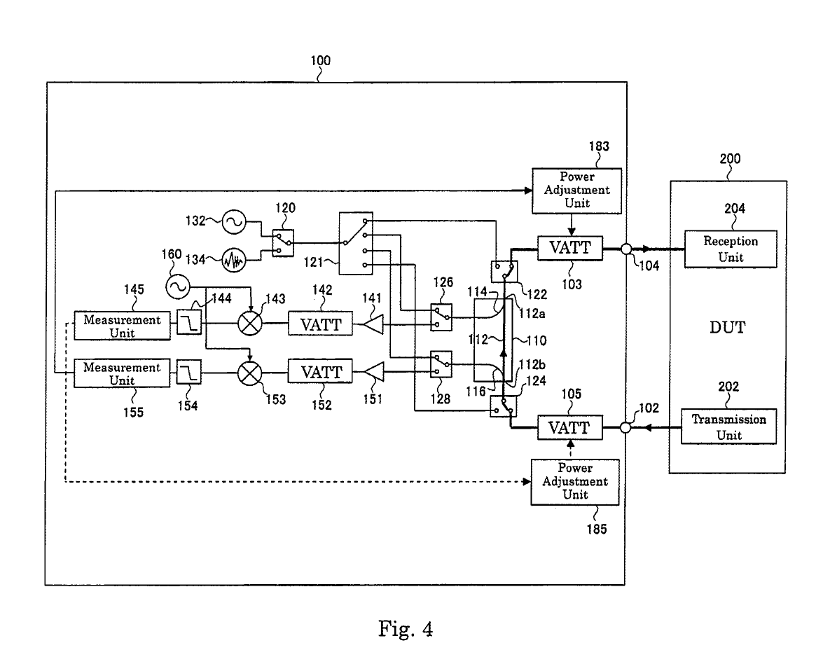

It should be noted that the power adjustment unit (electric power adjustment unit) 183 does not function in FIGS. 1 and 2. The power adjustment unit (electric power adjustment unit) 183 functions if the input port 102 and the output port 104 are replaced by each other (refer to FIGS. 3 and 4). The power adjustment unit 183 adjusts the electric power of an output port signal output from the output port 104 if the input port 102 and the output port 104 are connected with each other referring to FIGS. 3 and 4. Specifically, the power adjustment unit 183 adjusts the electric power of the output port signal by adjusting the ratio between the input and the output of the VATT 103.

The coupler 110 includes electrically conductive wires 112, 114, 116. An electric current flows through the electrically conductive wires 112, 114, 116.

The electrically conductive wire 112 includes one end 112a and the other end 112b. The current flows from the one end 112a to the other end 112b, or from the other end 112b to the one end 112a. The electrically conductive wire 114 connects the one end 112a and the switch 126 with each other. The electrically conductive wire 116 connects the other end 112b and the switch 128 with each other.

The switch 120 connects either one of the continuous wave signal source 132 and the noise source 134 to the switch 121.

The switch 122 connects the one end 112a to either one of the VATT 103 and the switch 121. The switch 124 connects the other end 112b to either one of the VATT 105 and the switch 121.

The switch 126 connects the electrically conductive wire 114 to either one of the amplifier 141 and the switch 121. The switch 128 connects the electrically conductive wire 116 to either one of the amplifier 151 and the switch 121.

The switch 121 connects the switch 120 to any one of the switches 122, 124, 126, 128.

The coupler 110, along with the switches 120, 121, 122, 124, 126, 128, constructs a connection unit.

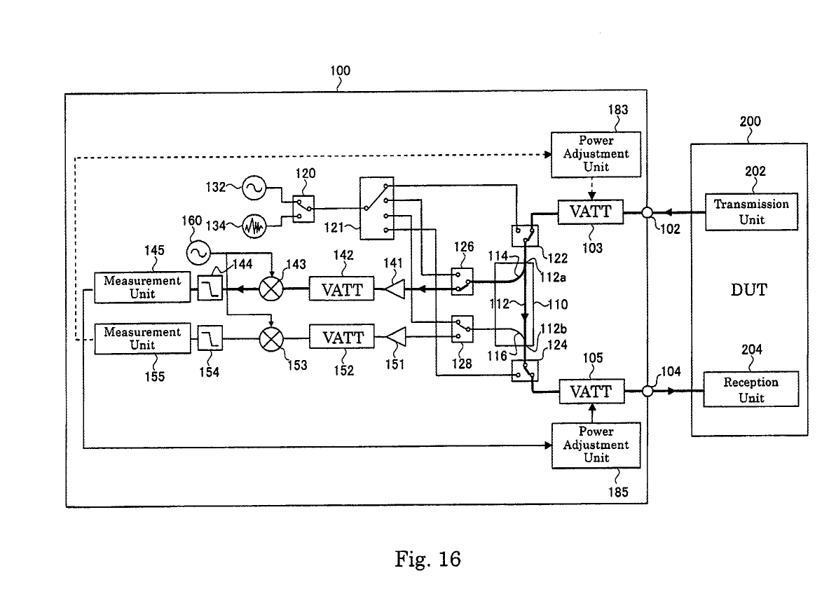

If the connection unit connects the one end 112a to the VATT 103, and simultaneously connects the electrically conductive wire 114 to the amplifier 141, the connection unit can consequently connect the input port 102 to the measurement unit 145 (refer to FIG. 1). On this occasion, if the connection unit further connects the other end 112b to the VATT 105, the connection unit can consequently connects the input port 102 to the measurement unit 145 and the output port 104 (refer to FIG. 16). If the connection unit connects the one end 112a to the VATT 103, and simultaneously connects the other end 112b to the VATT 105 (it should be noted that the electrically conductive wire 114 is connected to the switch 121), the connection unit can consequently connect the input port 102 to the output port 104 (refer to FIG. 2)

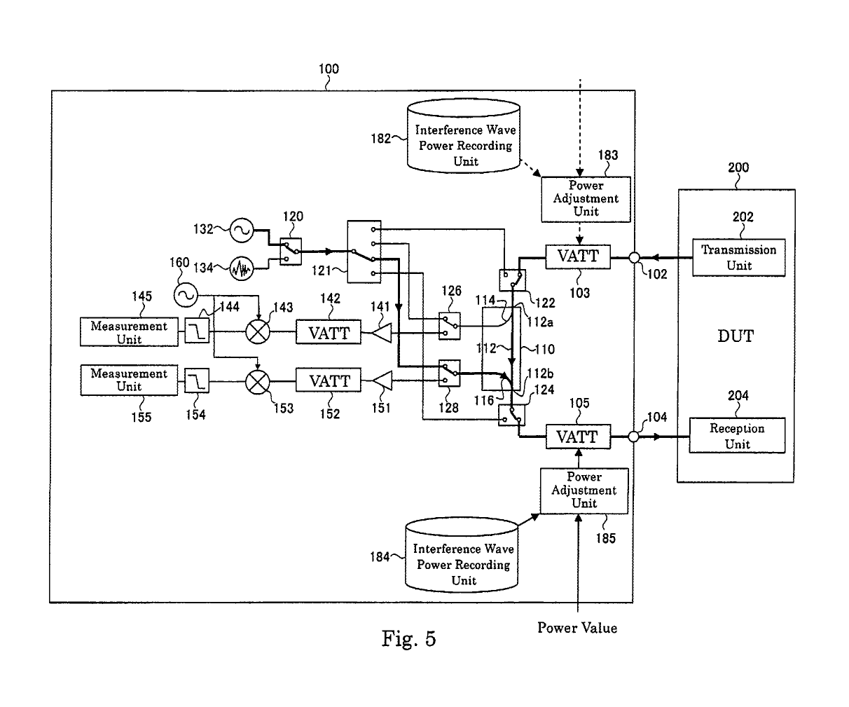

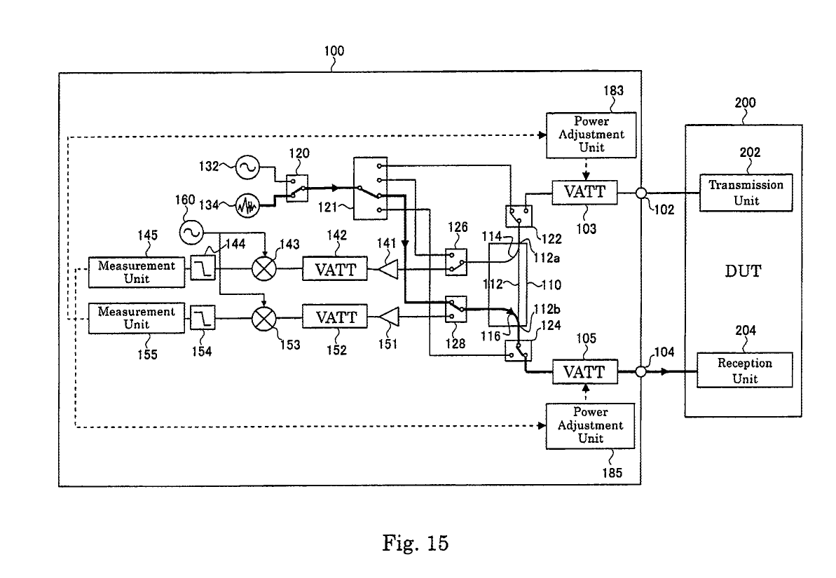

If the connection unit connects the other end 112b to the VATT 105, simultaneously connects the electrically conductive wire 116 to the switch 121, and simultaneously connects the switch 121 to the continuous wave signal source 132 or the noise source 134 (it should be noted that the one end 112a is connected to the switch 121), the connection unit can consequently connect the output port 104 to the continuous wave signal source 132 or the noise source 134 (signal output unit) (refer to FIG. 15). On this occasion, if the connection unit further connects the one end 112a to the VATT 103 (it should be noted that the electrically conductive wire 114 is connected to the switch 121), the connection unit can consequently connect the output port 104 to the continuous wave signal source 132 or the noise source 134 (signal output unit) and the input port 102 (refer to FIG. 5).

It should be noted that FIG. 15 is a functional block diagram showing a connection example in which the output port 104 is connected to the noise source 134 in the measurement device 100. Moreover, FIG. 16 is a functional block diagram showing a connection example in which the input port 102 is connected to the measurement unit 145 and the output port 104 in the measurement device 100.

A description will now be given of an operation of the first embodiment.

First, the switch 122 connects the one end 112a to the VATT 103 as shown in FIG. 1. Further, the switch 126 connects the electrically conductive wire 114 to the amplifier 141. On this occasion, the input port 102 is connected to the measurement unit 145.

A signal transmitted from the transmission unit 202 of the DUT 200 is fed to the measurement unit 145 via the input port 102, the VATT 103, the switch 122, the coupler 110, the switch 126, the amplifier 141, the VATT 142, the mixer 143, and the low-pass filter 144 on this occasion. A measurement result by the measurement unit 145 is the electric power of the input signal (the output from the low-pass filter 144). The value of the electric power output from the transmission unit 202 is obtained based on this measurement result.

Then, the switch 122 connects the one end 112a to the VATT 103 as shown in FIG. 2. Further, the switch 124 connects the other end 112b to the VATT 105. It should be noted that the switch 126 connects the electrically conductive wire 114 to the switch 121 (on this occasion, the switch 121 does not connect the switch 120 to the switch 126). The input port 102 is connected to the output port 104 via the VATT 103, the switch 122, the coupler 110, the switch 124, and the VATT 105 in this case. As a result, the signal transmitted from the transmission unit 202 of the DUT 200 is fed to the reception unit 204.

On this occasion, the power adjustment unit (electric power adjustment unit) 185 adjusts the electric power of the output port signal output from the output port 104 according to the measurement result by the measurement unit 145. The power adjustment unit 185 receives the measurement result by the measurement unit 145, thereby determining the value of the electric power output from the transmission unit 202, for example. The power adjustment unit 185 then determines a degree of attenuating the electric power output from the transmission unit 202 so that the electric power falls in a range of the electric power which the reception unit 204 can receive. Further, the power adjustment unit 185 properly adjusts the degree of the attenuation by the VATT 105, thereby the electric power of the output port signal falls in the range of the electric power which the reception unit 204 can receive.

According to the first embodiment, the measurement device 100 can be used, by configuring the connection unit (coupler 110, switches 120, 121, 122, 124, 126, 128), as an ordinary measurement device which carries out (1) the measurement of the output of the transmission unit 202 of the DUT 200 by the measurement unit 145 (refer to FIG. 1), and (2) the test of feeding the output from the continuous wave signal source 132 or the noise source 134 to the reception unit 204 of the DUT 200 (refer to FIG. 15).

Moreover, the measurement unit 100 can carry out, by configuring the connection unit (coupler 110, switches 120, 121, 122, 124, 126, 128), (3) the test of feeding the signal transmitted from the transmission unit 202 of the DUT 200 to the reception unit 204 by connecting the input port 102 to the output port 104 (refer to FIG. 2).

On this occasion, the power adjustment unit 185 adjusts the electric power of the output port signal output from the output port 104 according to the measurement result by the measurement unit 145. As a result, the electric power of the output port signal can be set within the range which the reception unit 204 can receive.

In the first place, while the electric power which the transmission unit 202 of the DUT 200 can output is high (in order to ensure that radio wave reaches an antenna of a reception unit), the electric power which can be input to the reception unit 204 of the DUT 200 is low (so as to receive radio wave even if it is weak). Thus, if the transmission unit 202 and the reception unit 204 are connected with each other, an excessive electric power may be fed to the reception unit 204. This problem can be solved by the power adjustment unit 185.

In other words, the measurement device 100 can be used as an ordinary measurement device, and can also carry out the test of feeding the signal transmitted from the transmission unit 202 of the DUT 200 to the reception unit 204 according to the first embodiment.

It should be noted that the input port 102 is arranged above the output port 104 on the sheet in FIG. 1 according to the first embodiment. However, it is conceivable that a variation in which the input port 102 and the output port 104 are replaced by each other so that the input port 102 is arranged below the output port 104 on the sheet in FIG. 1.

FIG. 3 is a functional block diagram showing a configuration of the measurement device 100 according to a variation of the first embodiment of the present invention (the input port 102 and the measurement unit 155 are connected with each other). FIG. 4 is a functional block diagram showing a configuration of the measurement device 100 according to the variation of the first embodiment of the present invention (the input port 102 and the output port 104 are connected with each other).

The input port 102 is arranged below the output port 104 on the sheets of FIGS. 3 and 4. This arrangement corresponds to an arrangement in which the transmission unit 202 is arranged below the reception unit 204 on the sheets of FIGS. 3 and 4.

The configuration of the measurement device in FIGS. 3 and 4 is the same as that of the first embodiment. However, the VATT 103 is connected to the output port 104, and the VATT 105 is connected to the input port 102.

A description will now be given of an operation of the variation of the first embodiment of the present invention.

First, the switch 124 connects the other end 112b to the VATT 105 as shown in FIG. 3. Further, the switch 128 connects the electrically conductive wire 116 to the amplifier 151. On this occasion, the input port 102 is connected to the measurement unit 155.

A signal transmitted from the transmission unit 202 of the DUT 200 is fed to the measurement unit 155 via the input port 102, the VATT 105, the switch 124, the coupler 110, the switch 128, the amplifier 151, the VATT 152, the mixer 153, and the low-pass filter 154 on this occasion. A measurement result by the measurement unit 155 is the electric power of the input signal (the output from the low-pass filter 154). The value of the electric power output from the transmission unit 202 is obtained based on this measurement result.

Then, the switch 122 connects the one end 112a to the VATT 103 as shown in FIG. 4. Further, the switch 124 connects the other end 112b to the VATT 105. It should be noted that the switch 128 connects the electrically conductive wire 116 to the switch 121 (on this occasion, the switch 121 does not connect the switch 120 to the switch 128). The input port 102 is connected to the output port 104 via the VATT 105, the switch 124, the coupler 110, the switch 122, and the VATT 103 in this case. As a result, the signal transmitted from the transmission unit 202 of the DUT 200 is fed to the reception unit 204.

On this occasion, the power adjustment unit (electric power adjustment unit) 183 adjusts the electric power of the output port signal output from the output port 104 according to the measurement result by the measurement unit 155. The power adjustment unit 183 receives the measurement result by the measurement unit 155, thereby determining the value of the electric power output from the transmission unit 202, for example. The power adjustment unit 183 then determines a degree of attenuating the electric power output from the transmission unit 202 so that the electric power falls in a range of the electric power which the reception unit 204 can receive. Further, the power adjustment unit 183 properly adjusts the degree of the attenuation by the VATT 103, thereby the electric power of the output port signal falls in the range of the electric power which the reception unit 204 can receive.

The variation of the first embodiment can adapt to the mutual replacement between the transmission unit 202 and the reception unit 204 of the DUT 200 (while the transmission unit 202 is above the reception unit 204 on the sheets of FIGS. 1 and 2, the transmission unit 202 is below the reception unit 204 on the sheets of FIGS. 3 and 4).

### Second Embodiment

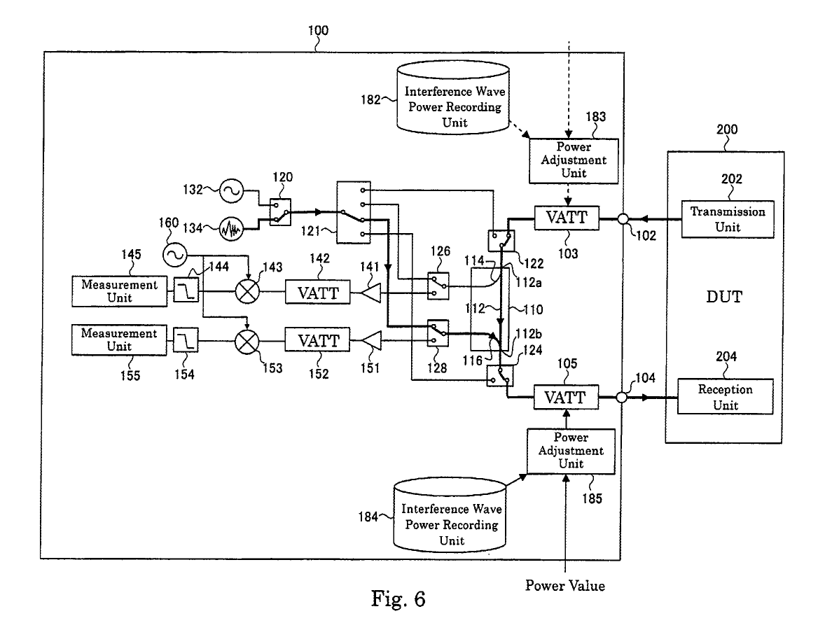

According to a second embodiment, the input port 102 and the output port 104 are connected with each other, and the continuous wave signal source 132 (refer to FIG. 5) or the noise source 134 (refer to FIG. 6) is simultaneously connected to the output port 104.

FIG. 5 is a functional block diagram showing a configuration of the measurement device 100 according to the second embodiment of the present invention (the continuous wave signal source 132 and the output port 104 are connected with each other). FIG. 6 is a functional block diagram showing a configuration of the measurement device 100 according to the second embodiment of the present invention (the noise source 134 and the output port 104 are connected with each other).

The measurement device 100 according to the second embodiment includes the input port 102, the output port 104, the variable attenuators (VATTs) 103, 105, the coupler 110, the switches 120, 121, 122, 124, 126, 128, the continuous wave signal source (signal output unit) 132, the noise source (signal output unit) 134, the amplifiers 141, 151, the variable attenuators (VATTs) 142, 152, the mixers 143, 153, the low-pass filters 144, 154, the measurement units (electric power measurement units) 145, 155, the local signal source 160, interference wave power recording units 182, 184, and the power adjustment units (electric power adjustment units) 183, 185. In the following section, the same components are denoted by the same numerals as of the first embodiment, and will be explained in no more details.

The input port 102, the output port 104, the variable attenuators (VATTs) 103, 105, the coupler 110, the switches 120, 121, 122, 124, 126, 128, the continuous wave signal source (signal output unit) 132, the noise source (signal output unit) 134, the amplifiers 141, 151, the variable attenuators (VATTs) 142, 152, the mixers 143, 153, the low-pass filters 144, 154, the measurement units 145, 155, and the local signal source 160 are the same as those of the first embodiment, and a description thereof, therefore, is omitted.

It should be noted that the other end 112b is connected to the VATT 105, the electrically conductive wire 116 is simultaneously connected to the switch 121, the switch 121 is simultaneously connected to the continuous wave signal source 132 (refer to FIG. 5) or the noise source 134 (refer to FIG. 6) and, the one end 112a is further connected to the VATT 103 (it should be noted that the electrically conductive wire 114 is connected to the switch 121). As a result, the output port 104 is connected to the continuous wave signal source 132 or the noise source 134 (signal output unit) and the input port 102 (refer to FIGS. 5 and 6).

The interference wave power recording units 182, 184 record the electric power (power) of the continuous wave signal and the noise. The continuous wave signal and the noise act as an interference wave on the signal fed to the reception unit 204 from the transmission unit 202.

It should be noted that the output port signal output from the output port 104 contains an output signal component which is the output signal (continuous wave signal or the noise) reaching the output port 104.

The power adjustment unit (electric power adjustment unit) 185 adjusts the electric power of the output signal component. Specifically, the power adjustment unit (electric power adjustment unit) 185 adjusts the electric power of the output signal component to a desired value by adjusting the ratio between the input and the output of the VATT 105. Though the output signal is the continuous wave signal or the noise, the powers of both of them are recorded in the interference wave power recording unit 184, and a degree of attenuating the output signal so that the electric power of the output signal component attains the desired value can be obtained. This desired value (power value) is instructed by a user to the power adjustment unit 185.

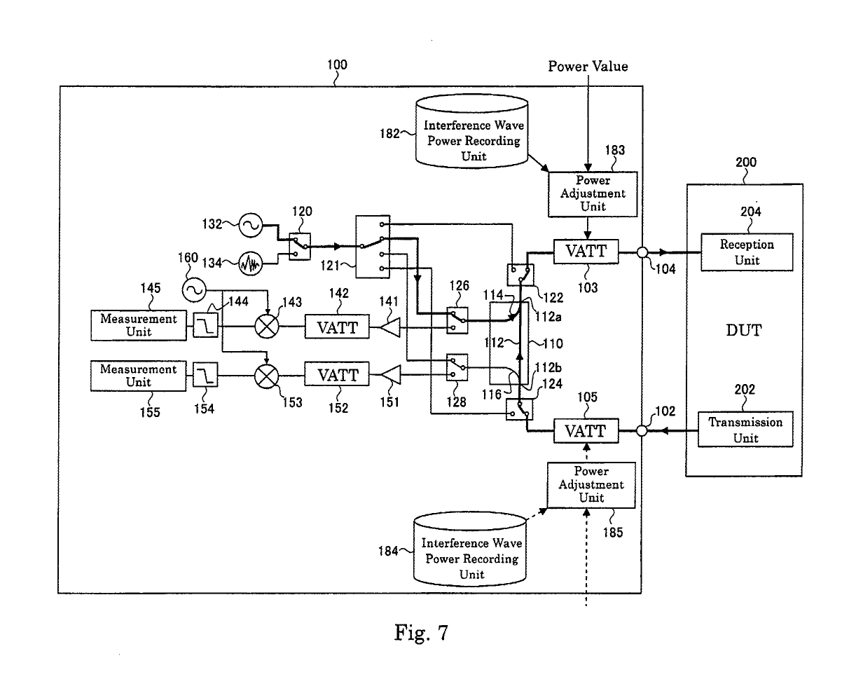

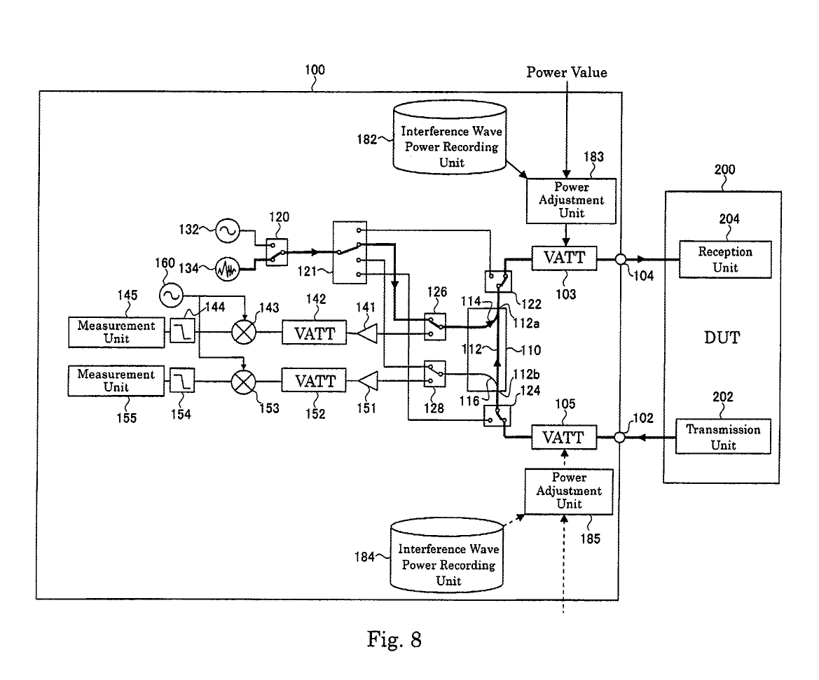

It should be noted that the power adjustment unit (electric power adjustment unit) 183 does not function in FIGS. 5 and 6. The power adjustment unit (electric power adjustment unit) 183 functions if the input port 102 and the output port 104 are replaced by each other (refer to FIGS. 7 and 8). The power adjustment unit 183 adjusts the electric power of the output signal component referring to FIGS. 7 and 8. Specifically, the power adjustment unit (electric power adjustment unit) 183 adjusts the electric power of the output signal component to the desired value by adjusting the ratio between the input and the output of the VATT 103. Though the output signal is the continuous wave signal or the noise, the powers of both of them are recorded in the interference wave power recording unit 182, and a degree of attenuating the output signal so that the electric power of the output signal component attains the desired value can be obtained. This desired value (power value) is instructed by the user to the power adjustment unit 183.

A description will now be given of an operation of the second embodiment.

The switch 122 connects the one end 112a to the VATT 103 as shown in FIGS. 5 and 6. Further, the switch 124 connects the other end 112b to the VATT 105. It should be noted that the switch 126 connects the electrically conductive wire 114 to the switch 121. Further, the switch 128 connects the electrically conductive wire 116 to the switch 121. Moreover, the switch 120 connects the switch 121 to the continuous wave signal source 132 (refer to FIG. 5) or the noise source 134 (refer to FIG. 6). Further, the switch 121 connects the switch 120 to the switch 128.

The input port 102 is connected to the output port 104 via the VATT 103, the switch 122, the coupler 110, the switch 124, and the VATT 105 in this case. As a result, the signal transmitted from the transmission unit 202 of the DUT 200 is fed to the reception unit 204.

Moreover, the output port 104 is connected to the continuous wave signal source 132 (refer to FIG. 5) or the noise source 134 (refer to FIG. 6) via the switch 120, the switch 121, the switch 128, the coupler 110, the switch 124, and the VATT 105.

The desired value (power value) of the electric power of the output signal component is fed to the power adjustment unit (electric power adjustment unit) 185 on this occasion. Further, the power adjustment unit 185 determines the degree of attenuating the output signal so that the electric power of the output signal component attains the desired value based on the powers of the continuous wave signal and the noise (output signal) recorded in the interference wave power recording unit 184 and the power value. The power adjustment unit 185 then properly adjusts the degree of the attenuation by the VATT 105 so that the electric power of the output signal component attains the desired value.

According to the second embodiment, the measurement device 100 can be used as an ordinary measurement device (refer to FIGS. 1 and 15), and can also carry out the test of feeding the signal obtained by adding the output from the continuous wave signal source 132 or the noise source 134 as the interference wave to the signal transmitted from the transmission unit 202 of the DUT 200 to the reception unit 204.

It should be noted that the input port 102 is arranged above the output port 104 on the sheet in FIG. 5 according to the second embodiment. However, it is conceivable that a variation in which the input port 102 and the output port 104 are replaced by each other so that the input port 102 is arranged below the output port 104 on the sheet in FIG. 5.

FIG. 7 is a functional block diagram showing a configuration of the measurement device 100 according to a variation of the second embodiment of the present invention (the continuous wave signal source 132 and the output port 104 are connected with each other). FIG. 8 is a functional block diagram showing a configuration of the measurement device 100 according to the variation of the second embodiment of the present invention (the noise source 134 and the output port 104 are connected with each other).

The input port 102 is arranged below the output port 104 in FIGS. 7 and 8. This arrangement corresponds to an arrangement in which the transmission unit 202 is arranged below the reception unit 204 on the sheets of FIGS. 7 and 8.

The configuration of the measurement device 100 in FIGS. 7 and 8 is the same as that of the second embodiment. However, the VATT 103 is connected to the output port 104, and the VATT 105 is connected to the input port 102.

A description will now be given of an operation of the variation of the second embodiment of the present invention.

The switch 122 connects the one end 112a to the VATT 103 as shown in FIGS. 7 and 8. Further, the switch 124 connects the other end 112b to the VATT 105. It should be noted that the switch 128 connects the electrically conductive wire 116 to the switch 121. Further, the switch 126 connects the electrically conductive wire 114 to the switch 121. Moreover, the switch 120 connects the switch 121 to the continuous wave signal source 132 (refer to FIG. 7) or the noise source 134 (refer to FIG. 8). Further, the switch 121 connects the switch 120 to the switch 126.

The input port 102 is connected to the output port 104 via the VATT 105, the switch 124, the coupler 110, the switch 122, and the VATT 103 in this case. As a result, the signal transmitted from the transmission unit 202 of the DUT 200 is fed to the reception unit 204.

Moreover, the output port 104 is connected to the continuous wave signal source 132 (refer to FIG. 7) or the noise source 134 (refer to FIG. 8) via the switch 120, the switch 121, the switch 126, the coupler 110, the switch 122, and the VATT 103.

A desired value (power value) of the electric power of the output signal component is fed to the power adjustment unit (electric power adjustment unit) 183 on this occasion. Further, the power adjustment unit 183 determines the degree of attenuating the output signal so that the electric power of the output signal component attains the desired value based on the powers of the continuous wave signal and the noise (output signal) recorded in the power recording unit 182 and the power value. The power adjustment unit 183 then properly adjusts the degree of the attenuation by the VATT 103 so that the electric power of the output signal component attains the desired value.

The variation of the second embodiment can adapt to the mutual replacement between the transmission unit 202 and the reception unit 204 of the DUT 200 (while the transmission unit 202 is above the reception unit 204 on the sheets of FIGS. 5 and 6, the transmission unit 202 is below the reception unit 204 on the sheets of FIGS. 7 and 8).

### Third Embodiment

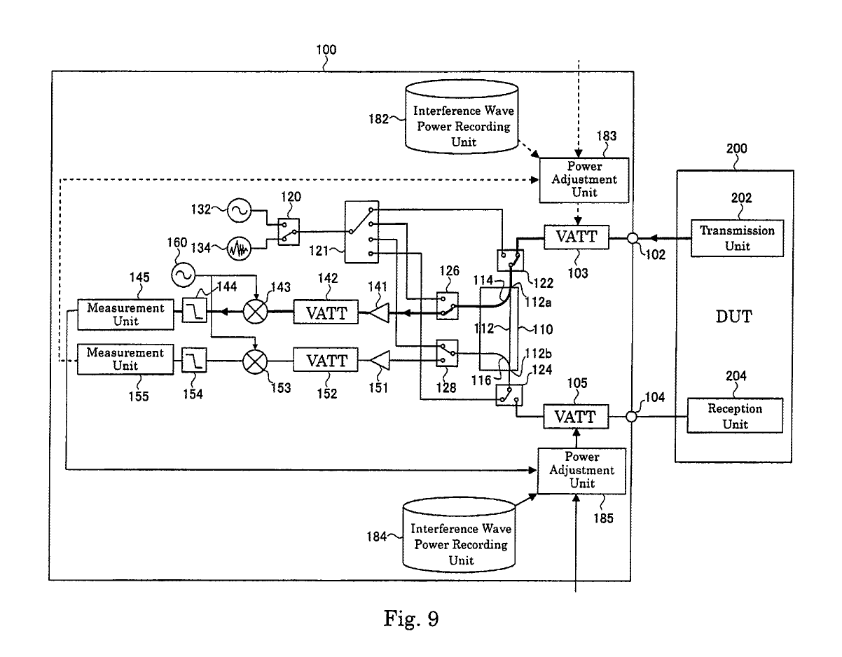

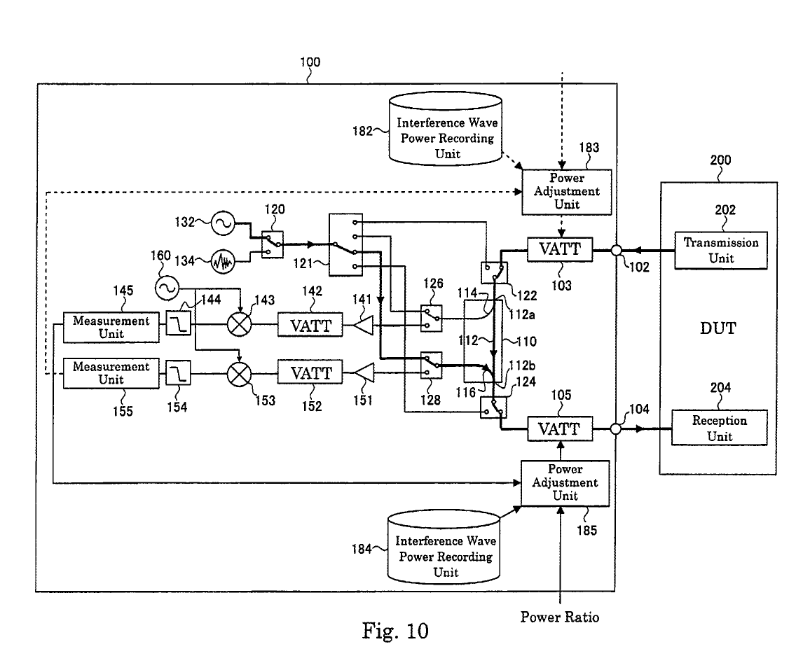

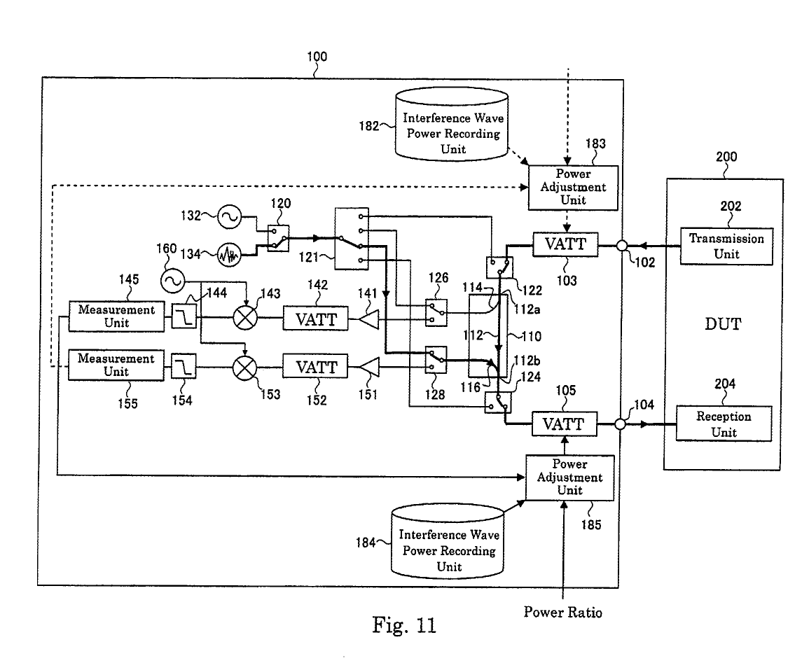

According to a third embodiment, the measurement by the measurement unit 145 is carried out (refer to FIG. 9), the input port 102 and the output port 104 are then connected with each other, and the continuous wave signal source 132 (refer to FIG. 10) or the noise source 134 (refer to FIG. 11) is simultaneously connected to the output port 104.

FIG. 9 is a functional block diagram showing a configuration of the measurement device 100 according to the third embodiment of the present invention (the input port 102 and the measurement unit 145 are connected with each other). FIG. 10 is a functional block diagram showing a configuration of the measurement device 100 according to the third embodiment of the present invention (the continuous wave signal source 132 and the output port 104 are connected with each other). FIG. 11 is a functional block diagram showing a configuration of the measurement device 100 according to the third embodiment of the present invention (the noise source 134 and the output port 104 are connected with each other).

The measurement device 100 according to the third embodiment includes the input port 102, the output port 104, the variable attenuators (VATTs) 103, 105, the coupler 110, the switches 120, 121, 122, 124, 126, 128, the continuous wave signal source (signal output unit) 132, the noise source (signal output unit) 134, the amplifiers 141, 151, the variable attenuators (VATTs) 142, 152, the mixers 143, 153, the low-pass filters 144, 154, the measurement units (electric power measurement units) 145, 155, the local signal source 160, the interference wave power recording units 182, 184, and the power adjustment units (electric power adjustment units) 183, 185. In the following section, the same components are denoted by the same numerals as of the first embodiment, and will be explained in no more details.

The input port 102, the output port 104, the variable attenuators (VATTs) 103, 105, the coupler 110, the switches 120, 121, 122, 124, 126, 128, the continuous wave signal source (signal output unit) 132, the noise source (signal output unit) 134, the amplifiers 141, 151, the variable attenuators (VATTs) 142, 152, the mixers 143, 153, the low-pass filters 144, 154, the measurement units 145, 155, and the local signal source 160 are the same as those of the first embodiment, and a description thereof, therefore, is omitted.

It should be noted that the one end 112a is first connected to the VATT 103, and the electrically conductive wire 114 is connected to the amplifier 141 (refer to FIG. 9). In this case, the input port 102 can be connected to the measurement unit 145 as in the first embodiment. A measurement result by the measurement unit 145 is the electric power of the input signal (the output from the low-pass filter 144). The value of the electric power output from the transmission unit 202 is obtained based on this measurement result.

Then, the other end 112b is connected to the VATT 105, the electrically conductive wire 116 is simultaneously connected to the switch 121, the switch 121 is simultaneously connected to the continuous wave signal source 132 (refer to FIG. 10) or the noise source 134 (refer to FIG. 11), and the one end 112a is further connected to the VATT 103 (it should be noted that the electrically conductive wire 114 is connected to the switch 121). As a result, the input port 102 and the output port 104 are connected with each other, and the output port 104 is simultaneously connected to the continuous wave signal source 132 or the noise source 134 (signal output unit) (refer to FIGS. 10 and 11).

The interference wave power recording units 182, 184 record the electric power (power) of the continuous wave signal and the noise as in the second embodiment. The continuous wave signal and the noise act as an interference wave on the signal fed to the reception unit 204 from the transmission unit 202.

It should be noted that the output port signal output from the output port 104 if the input port 102 and the output port 104 are connected with each other (refer to FIGS. 10 and 11) contains an output signal component which is the output signal (continuous wave signal or the noise) reaching the output port 104 as in the second embodiment. The output port signal further contains an input port signal component which is an input port signal input from the input port 102 reaching the output port 104.

The power adjustment unit (electric power adjustment unit) 185 adjusts the electric power of the output signal component if the input port 102 and the output port 104 are connected with each other (FIGS. 10 and 11). Specifically, the power adjustment unit (electric power adjustment unit) 185 adjusts a ratio between the electric power of the output signal component and the electric power of the input port signal component to a desired value (power ratio) by adjusting the ratio between the input and the output of the VATT 105.

The output signal is the continuous wave signal or the noise, and the powers of both of them are recorded in the interference wave power recording unit 184. Moreover, the electric power of the input port signal component is obtained by a measurement result by the measurement unit 145 (refer to FIG. 9). As a result, a degree of attenuating the output signal so that the ratio between the electric power of the output signal component and the electric power of the input port signal component attains the desired value (power ratio) can be obtained. This desired value (power ratio) is instructed by the user to the power adjustment unit 185.

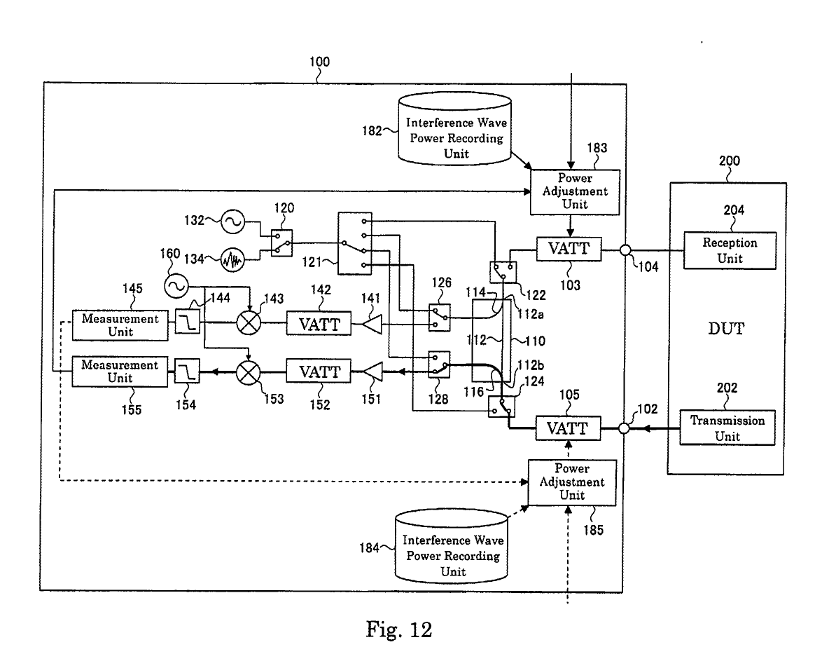

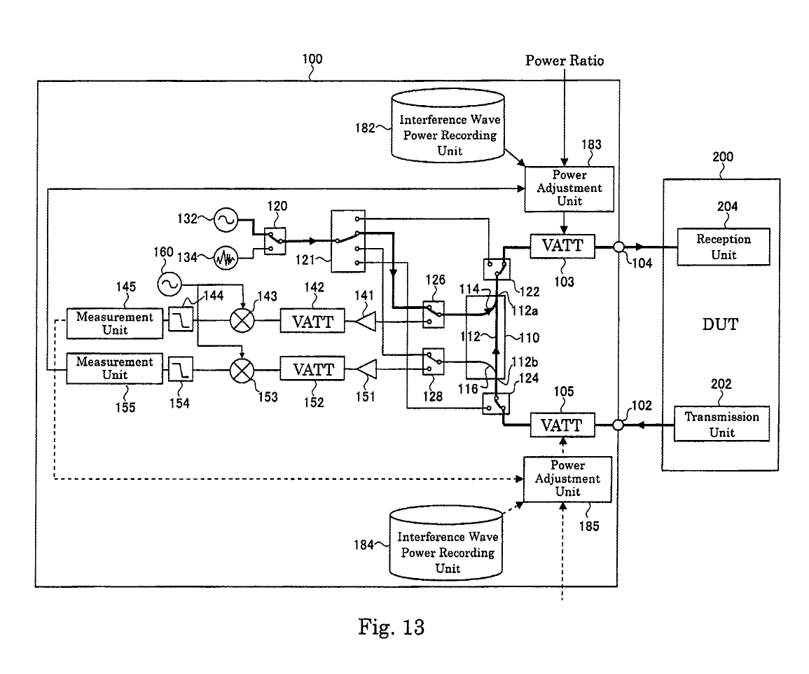

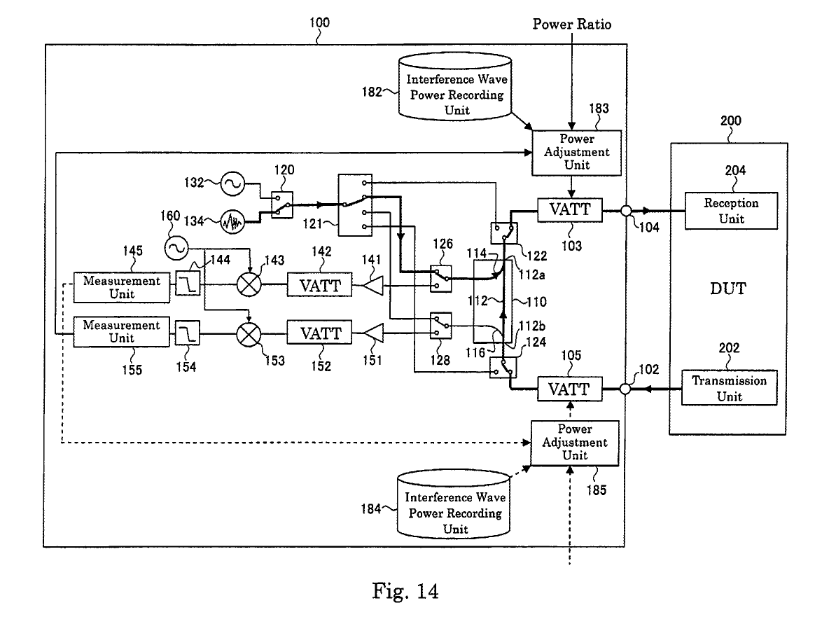

It should be noted that the power adjustment unit (electric power adjustment unit) 183 does not function in FIGS. 9, 10, and 11. The power adjustment unit (electric power adjustment unit) 183 functions if the input port 102 and the output port 104 are replaced by each other (refer to FIGS. 12, 13, and 14). The power adjustment unit 183 adjusts the electric power of the output signal component referring to FIGS. 13 and 14. Specifically, the power adjustment unit 183 adjusts the ratio between the electric power of the output signal component and the electric power of the input port signal component to the desired value by adjusting the ratio between the input and the output of the VATT 103.

The output signal is the continuous wave signal or the noise, and the powers of both of them are recorded in the interference wave power recording unit 182. Moreover, the electric power of the input port signal component is obtained by a measurement result by the measurement unit 155 (refer to FIG. 12). As a result, a degree of attenuating the output signal so that the ratio between the electric power of the output signal component and the electric power of the input port signal component attains the desired value (power ratio) can be obtained. This desired value (power value) is instructed by the user to the power adjustment unit 183 (refer to FIGS. 13 and 14).

A description will now be given of an operation of the third embodiment.

First, the switch 122 connects the one end 112a to the VATT 103 as shown in FIG. 9. Further, the switch 126 connects the electrically conductive wire 114 to the amplifier 141. On this occasion, the input port 102 is connected to the measurement unit 145.

A signal transmitted from the transmission unit 202 of the DUT 200 is fed to the measurement unit 145 via the input port 102, the VATT 103, the switch 122, the coupler 110, the switch 126, the amplifier 141, the VATT 142, the mixer 143, and the low-pass filter 144 on this occasion. A measurement result by the measurement unit 145 is the electric power of the input signal (the output from the low-pass filter 144). The value of the electric power output from the transmission unit 202 is obtained based on this measurement result.

Then, the switch 122 connects the one end 112a to the VATT 103 as shown in FIGS. 10 and 11. Further, the switch 124 connects the other end 112b to the VATT 105. It should be noted that the switch 126 connects the electrically conductive wire 114 to the switch 121. Further, the switch 128 connects the electrically conductive wire 116 to the switch 121. Moreover, the switch 120 connects the switch 121 to the continuous wave signal source 132 (refer to FIG. 10) or the noise source 134 (refer to FIG. 11). Further, the switch 121 connects the switch 120 to the switch 128.

The input port 102 is connected to the output port 104 via the VATT 103, the switch 122, the coupler 110, the switch 124, and the VATT 105 in this case. As a result, the signal transmitted from the transmission unit 202 of the DUT 200 is fed to the reception unit 204.

Moreover, the output port 104 is connected to the continuous wave signal source 132 (refer to FIG. 10) or the noise source 134 (refer to FIG. 11) via the switch 120, the switch 121, the switch 128, the coupler 110, the switch 124, and the VATT 105.

The desired value (power ratio) of the ratio between the electric power of the output signal component and the electric power of the input port signal component is fed to the power adjustment unit (electric power adjustment unit) 185 on this occasion. The powers of the continuous wave signal and the noise (output signal) recorded in the interference wave power recording unit 184, and the measurement result by the measurement unit 145 are further fed to the power adjustment unit 185. The electric power of the input port signal component is obtained by the power adjustment unit 185 from the measurement result by the measurement unit 145 (refer to FIG. 9).

The power adjustment unit 185 can obtain a degree of attenuating the output signal so that the ratio between the electric power of the output signal component and the electric power of the input port signal component attains the desired value based on the electric power of the input port signal component, the power ratio, and the power of the output signal. The power adjustment unit 185 then properly adjusts the degree of the attenuation by the VATT 105 so that the ratio between the electric power of the output signal component and the electric power of the input port signal component attains the desired value.

It should be noted that the power adjustment unit 185 may adjust the electric power of the output port signal output from the output port 104 according to the measurement result by the measurement unit 145 as in the first embodiment.

According to the third embodiment, the same effects as in the second embodiment can be provided, and the ratio between the electric power of the output signal component and the electric power of the input port signal component can further attain the desired value (power ratio).

It should be noted that the input port 102 is arranged above the output port 104 on the sheets in FIGS. 9 to 11 according to the third embodiment. However, it is conceivable that a variation in which the input port 102 and the output port 104 are replaced by each other so that the input port 102 is arranged below the output port 104 on the sheets in FIGS. 9 to 11.

FIG. 12 is a functional block diagram showing a configuration of the measurement device 100 according to a variation of the third embodiment of the present invention (the input port 102 and the measurement unit 155 are connected with each other). FIG. 13 is a functional block diagram showing a configuration of the measurement device 100 according to the variation of the third embodiment of the present invention (the continuous wave signal source 132 and the output port 104 are connected with each other). FIG. 14 is a functional block diagram showing a configuration of the measurement device 100 according to the variation of the third embodiment of the present invention (the noise source 134 and the output port 104 are connected with each other).

The input port 102 is arranged below the output port 104 in FIGS. 12 to 14. This arrangement corresponds to an arrangement in which the transmission unit 202 is arranged below the reception unit 204 on the sheets of FIGS. 12 to 14.

The configuration of the measurement device 100 in FIGS. 12 to 14 is the same as that of the third embodiment. However, the VATT 103 is connected to the output port 104, and the VATT 105 is connected to the input port 102.

A description will now be given of an operation of the variation of the third embodiment of the present invention.

First, the switch 124 connects the other end 112b to the VATT 105 as shown in FIG. 12. Further, the switch 128 connects the electrically conductive wire 116 to the amplifier 151. On this occasion, the input port 102 is connected to the measurement unit 155.

A signal transmitted from the transmission unit 202 of the DUT 200 is fed to the measurement unit 155 via the input port 102, the VATT 105, the switch 124, the coupler 110, the switch 128, the amplifier 151, the VATT 152, the mixer 153, and the low-pass filter 154 on this occasion. A measurement result by the measurement unit 155 is the electric power of the input signal (the output from the low-pass filter 154). The value of the electric power output from the transmission unit 202 is obtained based on this measurement result.

Then, the switch 122 connects the one end 112a to the VATT 103 as shown in FIGS. 13 and 14. Further, the switch 124 connects the other end 112b to the VATT 105. It should be noted that the switch 128 connects the electrically conductive wire 116 to the switch 121. Further, the switch 126 connects the electrically conductive wire 114 to the switch 121. Moreover, the switch 120 connects the switch 121 to the continuous wave signal source 132 (refer to FIG. 13) or the noise source 134 (refer to FIG. 14). Further, the switch 121 connects the switch 120 to the switch 126.

The input port 102 is connected to the output port 104 via the VATT 105, the switch 124, the coupler 110, the switch 122, and the VATT 103 in this case. As a result, the signal transmitted from the transmission unit 202 of the DUT 200 is fed to the reception unit 204.

Moreover, the output port 104 is connected to the continuous wave signal source 132 (refer to FIG. 13) or the noise source 134 (refer to FIG. 14) via the switch 120, the switch 121, the switch 126, the coupler 110, the switch 122, and the VATT 103.

A desired value (power ratio) of the ratio between the electric power of the output signal component and the electric power of the input port signal component is fed to the power adjustment unit (electric power adjustment unit) 183 on this occasion. The powers of the continuous wave signal and the noise (output signal) recorded in the interference wave power recording unit 182, and the measurement result by the measurement unit 155 are further fed to the power adjustment unit 183. The electric power of the input port signal component is obtained by the power adjustment unit 183 from the measurement result by the measurement unit 155 (refer to FIG. 12).

The power adjustment unit 183 can obtain a degree of attenuating the output signal so that the ratio between the electric power of the output signal component and the electric power of the input port signal component attains the desired value based on the electric power of the input port signal component, the power ratio, and the power of the output signal. The power adjustment unit 183 then properly adjusts the degree of the attenuation by the VATT 103 so that the ratio between the electric power of the output signal component and the electric power of the input port signal component attains the desired value.

It should be noted that the power adjustment unit 183 may adjust the electric power of the output port signal output from the output port 104 according to the measurement result by the measurement unit 155 as in the variation of the first embodiment.

The variation of the third embodiment can adapt to the mutual replacement between the transmission unit 202 and the reception unit 204 of the DUT 200 (while the transmission unit 202 is above the reception unit 204 on the sheets of FIGS. 9 to 11, the transmission unit 202 is below the reception unit 204 on the sheets of FIGS. 12 to 14).

### Fourth Embodiment

According to a fourth embodiment, (1) the switch 122 is removed, and the one end 112a is directly connected to the VATT 103, (2) the connection between the switch 121 and the switch 122 no longer exits as a result of the removal of the switch 122, and (3) switches 124a, 124b, and 124c are provided in place of the switch 124 in the second embodiment (refer to FIGS. 5 and 6).

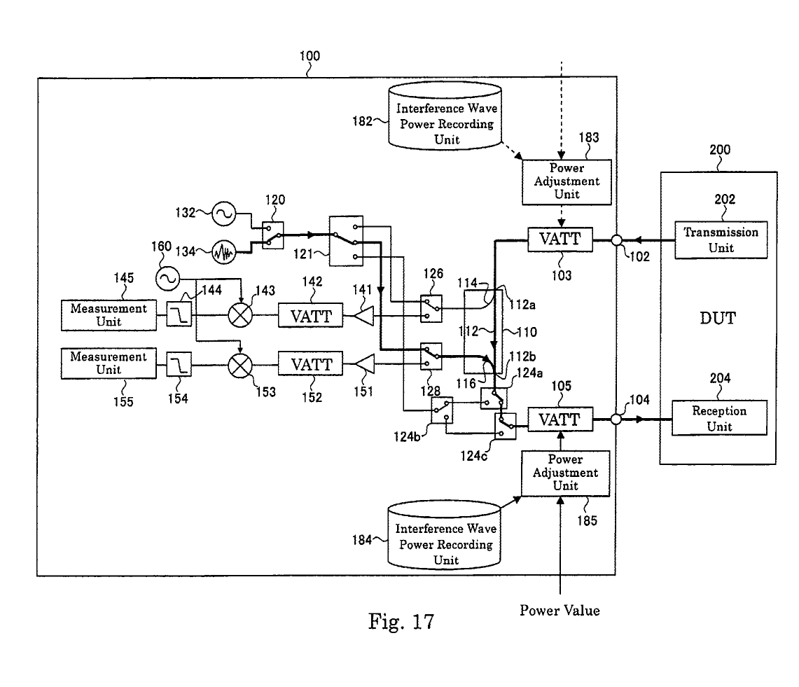

FIG. 17 is a functional block diagram showing a configuration of the measurement device 100 according to the fourth embodiment of the present invention (the noise source 134 and the input port 102, and the output port 104 are connected with each other). It should be noted that the continuous wave signal source 132 and the output port 104 can be connected by switching the switch 120.

The measurement device 100 according to the fourth embodiment includes the input port 102, the output port 104, the variable attenuators (VATTs) 103, 105, the coupler 110, the switches 120, 121, 124a, 124b, 124c, 126, 128, the continuous wave signal source (signal output unit) 132, the noise source (signal output unit) 134, the amplifiers 141, 151, the variable attenuators (VATTs) 142, 152, the mixers 143, 153, the low-pass filters 144, 154, the measurement units (electric power measurement units) 145, 155, the local signal source 160, the interference wave power recording units 182, 184, and the power adjustment units (electric power adjustment units) 183, 185. In the following section, the same components are denoted by the same numerals as of the second embodiment, and will be explained in no more details.

The input port 102, the output port 104, variable attenuators (VATTs) 103, 105, the coupler 110, switches 120, 126, 128, a continuous wave signal source (signal output unit) 132, a noise source (signal output unit) 134, amplifiers 141, 151, variable attenuators (VATTs) 142, 152, mixers 143, 153, low-pass filters 144, 154, measurement units 145, 155, a local signal source 160, interference wave power recording units 182, 184, and power adjustment units (electric power adjustment units) 183, 185 are the same as those of the second embodiment, and a description thereof, therefore, is omitted.

The switch 122 is removed, and the one end 112a is directly connected to the VATT 103. The switch 121 is no longer connected to the switch 122 as a result of the removal of the switch 122.

The switch 124a connects the other end 112b to the switch 124b or 124c. The switch 124b connects the switch 121 to the switch 124a or 124c. The switch 124c connects the VATT 105 to the switch 124a or 124b.

It should be noted that the other end 112b is connected to the VATT 105 via the switches 124a, 124c, the electrically conductive wire 116 is connected to the switch 121, and the switch 121 is connected to the continuous wave signal source 132 or the noise source 134 (refer to FIG. 17). Further, the one end 112a is directly connected to the VATT 103. As a result, the output port 104 is connected to the continuous wave signal source 132 or the noise source 134 (signal output unit) and the input port 102 (refer to FIG. 17).

A description will now be given of an operation of the fourth embodiment.

The one end 112a is directly connected to the VATT 103 as shown in FIG. 17. Further, the switches 124a, 124c connect the other end 112b to the VATT 105. Further, the switch 128 connects the electrically conductive wire 116 to the switch 121. Moreover, the switch 120 connects the switch 121 to the continuous wave signal source 132 or the noise source 134 (refer to FIG. 17). Further, the switch 121 connects the switch 120 to the switch 128.

The input port 102 is connected to the output port 104 via the VATT 103, the coupler 110, the switches 124a, 124c, and the VATT 105 in this case. As a result, the signal transmitted from the transmission unit 202 of the DUT 200 is fed to the reception unit 204.

Moreover, the output port 104 is connected to the continuous wave signal source 132 or the noise source 134 via the switch 120, the switch 121, the switch 128, the coupler 110, the switches 124a, 124c, and the VATT 105 (refer to FIG. 17).

The desired value (power value) of the electric power of the output signal component is fed to the power adjustment unit (electric power adjustment unit) 185 on this occasion. Further, the power adjustment unit 185 determines the degree of attenuating the output signal so that the electric power of the output signal component attains the desired value based on the powers of the continuous wave signal and the noise (output signal) recorded in the interference wave power recording unit 184 and the power value. The power adjustment unit 185 then properly adjusts the degree of the attenuation by the VATT 105 so that the electric power of the output signal component attains the desired value.

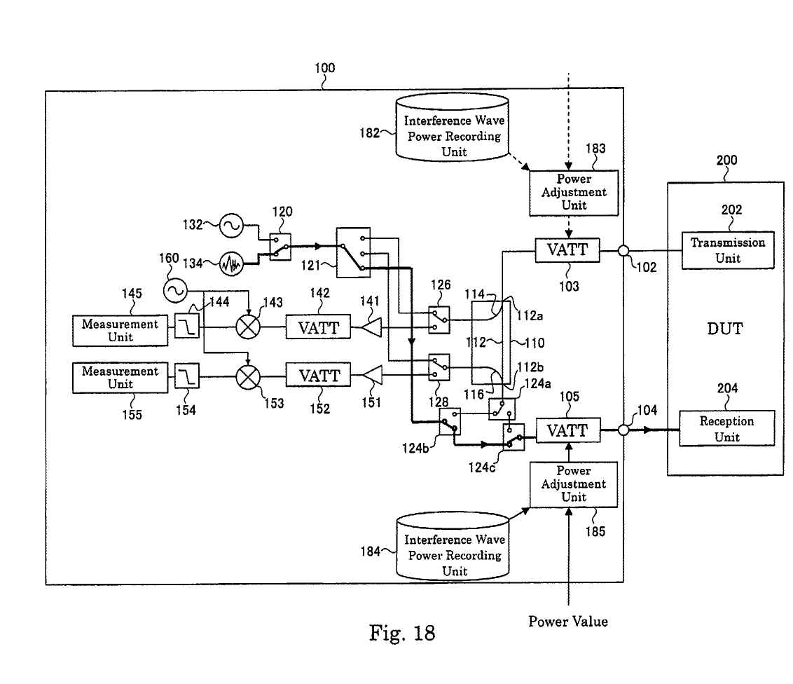

According to the fourth embodiment, the measurement device 100 can be used as an ordinary measurement device (refer to FIG. 18 described later), and can also carry out the test of feeding the signal obtained by adding the output from the continuous wave signal source 132 or the noise source 134 as the interference wave to the signal transmitted from the transmission unit 202 of the DUT 200 to the reception unit 204.

FIG. 18 is a functional block diagram showing a configuration in which the measurement device 100 according to the fourth embodiment of the present invention is used as an ordinary measurement device (the noise source 134 and the output port 104 are connected with each other).

The switches 124b, 124c connect the switch 121 to the VATT 105. Moreover, the switch 120 connects the switch 121 to the continuous wave signal source 132 or the noise source 134 (refer to FIG. 18). Further, the switch 121 connects the switch 120 to the switch 124b.

In this case, the output port 104 is connected to the continuous wave signal source 132 or the noise source 134 via the switch 120, the switch 121, the switches 124b, 124c, and the VATT 105 (refer to FIG. 18).

It should be noted that if the switch 121 does not connect the switch 120 and the switch 128 with each other, while the input port 102 and the output port 104 are still connected, the noise source 134 is not connected to the output port 104 in FIG. 17.

Moreover, if the switch 126 connects the electrically conductive wire 114 to the amplifier 141, the input port 102 can be connected to the output port 104 and the measurement unit 145 in FIG. 17. If the switch 124a further connects the other end 112b to the switch 124b on this occasion, the input port 102 is not connected to the output port 104, and is still connected to the measurement unit 145. The measurement result by the measurement unit 145 can be obtained in this case, and the connection configuration shown in FIG. 17 enables the adjustment of the output power (by the power adjustment unit 185) according to the measurement result as in the third embodiment.

It should be noted that the input port 102 is arranged above the output port 104 on the sheets in FIGS. 17 and 18 according to the fourth embodiment. However, it is conceivable that a variation in which the input port 102 and the output port 104 are replaced by each other so that the input port 102 is arranged below the output port 104 on the sheets in FIGS. 17 and 18.

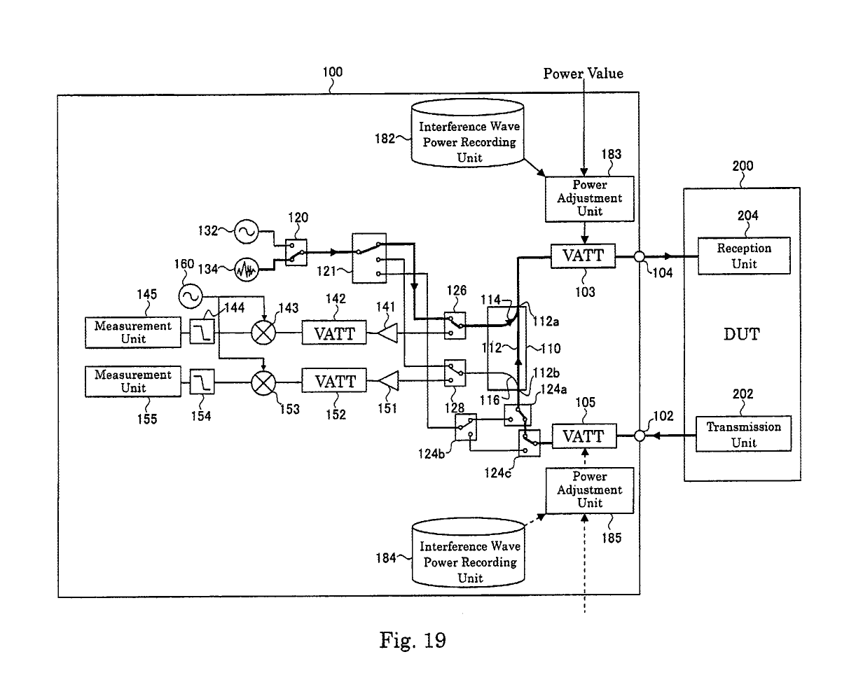

FIG. 19 is a functional block diagram showing a configuration of the measurement device 100 according to a variation of the fourth embodiment of the present invention (the noise source 134 and the input port 102, and the output port 104 are connected with each other).

The input port 102 is arranged below the output port 104 in FIG. 19. This arrangement corresponds to an arrangement in which the transmission unit 202 is arranged below the reception unit 204 on the sheet of FIG. 19.

The configuration of the measurement device 100 in FIG. 19 is the same as that of the third embodiment. However, the VATT 103 is connected to the output port 104, and the VATT 105 is connected to the input port 102. Moreover, the switch 126 connects the switch 121 to the electrically conductive wire 114. The switch 121 connects the switch 120 to the switch 126.

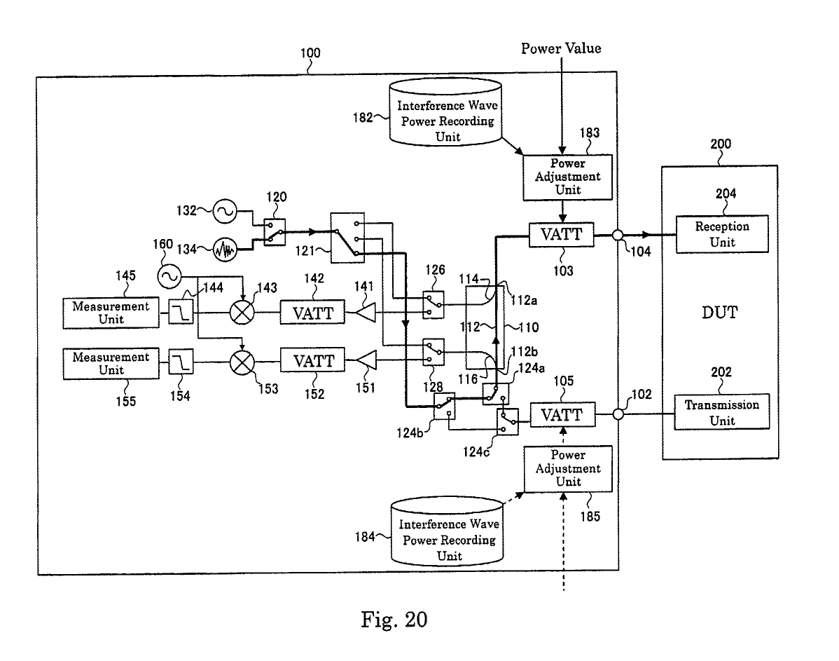

FIG. 20 is a functional block diagram showing a configuration in which the measurement device 100 according to the variation of the fourth embodiment of the present invention is used as an ordinary measurement device (the noise source 134 and the output port 104 are connected with each other).

The switches 124b, 124a connect the switch 121 to the VATT 103 via the coupler 110. Moreover, the switch 120 connects the switch 121 to the continuous wave signal source 132 or the noise source 134 (refer to FIG. 20). Further, the switch 121 connects the switch 120 to the switch 124b.

In this case, the output port 104 is connected to the continuous wave signal source 132 or the noise source 134 via the switch 120, the switch 121, the switches 124b, 124a, the coupler 110 and the VATT 103 (refer to FIG. 20).

1. A measurement device connected to a device under test including a transmission unit and a reception unit,
comprising:
an input port connected to the transmission unit;
an output port connected to the reception unit;
a signal output unit that outputs an output signal.
an electric power measurement unit that measures the electric power of an input signal;
a connection unit that can connect the input port to the output port and/or the electric power measurement unit, and can connect the output port to the input port and/or the signal output unit; and
an electric power adjustment unit that adjusts the electric power of an output port signal output from the output port if the input port and the output port are connected to each other.

2. The measurement device according to claim 1, wherein:
the connection unit connects the input port and the electric power measurement unit, then connects the input port and the output port with each other; and
the electric power adjustment unit adjusts the electric power of the output port signal according to a measurement result by the electric power measurement unit if the input port and the output port are connected with each other.

3. The measurement device according to claim 2, wherein the connection unit connects the input port and the output port, and simultaneously connects the output port and the signal output unit.

4. The measurement device according to claim 3, wherein:
the output port signal includes an output signal component which is the output signal, and has reached the output port, and an input port signal component which is an input port signal, is input from the input port, and has reached the output port if the input port and the output port are connected with each other; and
the electric power adjustment unit adjusts a ratio between the electric power of the output signal component and the electric power of the input port signal component contained in the output port signal if the input port and the output port are connected with each other.

5. The measurement device according to claim 1, wherein:
the connection unit connects the input port and the output port, and simultaneously connects the output port and the signal output unit;
the output port signal includes an output signal component which is the output signal and has reached the output port; and
the electric power adjustment unit adjusts the electric power of the output signal component.

6. The measurement device according to claim 1, wherein the output signal is a continuous wave signal or a noise.

7. The measurement device according to claim 1, wherein the input port and the output port are mutually replaceable.

8. The measurement device according to claim 2, wherein the output signal is a continuous wave signal or a noise.

9. The measurement device according to claim 3, wherein the output signal is a continuous wave signal or a noise.

10. The measurement device according to claim 4, wherein the output signal is a continuous wave signal or a noise.

11. The measurement device according to claim 5, wherein the output signal is a continuous wave signal or a noise.

12. The measurement device according to claim 2, wherein the input port and the output port are mutually replaceable.

13. The measurement device according to claim 3, wherein the input port and the output port are mutually replaceable.

14. The measurement device according to claim 4, wherein the input port and the output port are mutually replaceable.

15. The measurement device according to claim 5, wherein the input port and the output port are mutually replaceable.
